(19) United States
(12) Patent Application Publication
(10) Pub. No.: US 2025/0367773 A1
(43) Pub. Date: Dec. 4, 2025

(54) FIXTURE

(71) Applicant: GlobalFoundries U.S. Inc., Malta, NY (US)

(72) Inventor: Michael McCormick Raga-Barone, Ballston Spa, NY (US)

(21) Appl. No.: 18/676,963

(22) Filed: May 29, 2024

(51) Int. Cl. B23Q 3/06

(52) U.S. Cl. CPC B23Q 3/06; B23Q 2703/02

(57) ABSTRACT

The present disclosure relates to a fixture and, more particularly, to a fixture for the transport and storage of wafers and methods of use. The fixture includes: a frame having a mounting space provided between a top section, a bottom section and rails extending between the top section and the bottom section; and a clamp slidably mounted to the rails, the clamp including a locking mechanism that locks the clamp to the frame at different heights of the rails.

### BACKGROUND

The present disclosure relates to a fixture and, more particularly, to a fixture for the transport and storage of wafers and methods of use.

Horizontal wafer shippers can be used to transport and store semiconductor wafers. Also, Automated Material Handling Systems (AMHS) ensure efficient transport of material, e.g., semiconductor wafers, from one place to another in a manufacturing facility of a semiconductor fab. For example, the AMHS can transport semiconductor wafers throughout different manufacturing areas for different manufacturing processes. However, horizontal wafer shippers may not be compatible with AMHS/OHT (overhead transport) and, as such, require significant and expensive equipment to automate material handling.

### SUMMARY

In an aspect of the disclosure, a fixture comprises: a frame comprising a mounting space provided between a top section, a bottom section and rails extending between the top section and the bottom section; and a clamp slidably mounted to the rails, the clamp including a locking mechanism that locks the clamp to the frame at different heights of the rails.

In an aspect of the disclosure, a fixture comprises: a frame comprising rails each with a groove along a longitudinal axis and which are defined by opposing inwardly extending flanges; and a locking mechanism slidably mounted to the rails and which rotatably engages with one of the opposing inwardly extending flanges.

In an aspect of the disclosure, a fixture comprises: a frame comprising rails extending between a top section and a bottom section, the rails comprising a groove along a longitudinal axis; and a locking mechanism slidably mounted within the groove of the rails, the locking mechanism comprising a rotating cam mechanism and opposing channels between a main body and protrusions extending from a flange, the channels riding along the rails and the rotating cam mechanism being rotatable into and out of contact the rails.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a fixture in accordance with aspects of the present disclosure.

FIG. 2 shows a rail of the fixture in accordance with aspects of the present disclosure.

FIGS. 3A-3C show various views of a clamp used in the fixture in accordance with aspects of the present disclosure.

FIG. 4 shows a cam mechanism of the clamp engaging with the rail of the fixture in accordance with aspects of the present disclosure.

### DETAILED DESCRIPTION

The present disclosure relates to a fixture and, more particularly, to a fixture for the transport and storage of wafers and methods of use. More specifically, the present disclosure is directed to a fixture that securely holds a horizontal wafer shipper (HWS) while being compatible with an Automated Material Handling System (AMHS). The fixture allows horizontal wafer shipper packing tools to be placed anywhere in a semiconductor fab, while also reducing manual handling of the horizontal wafer shipper. Advantageously, the fixture can hold any style of horizontal wafer shipper regardless of its height.

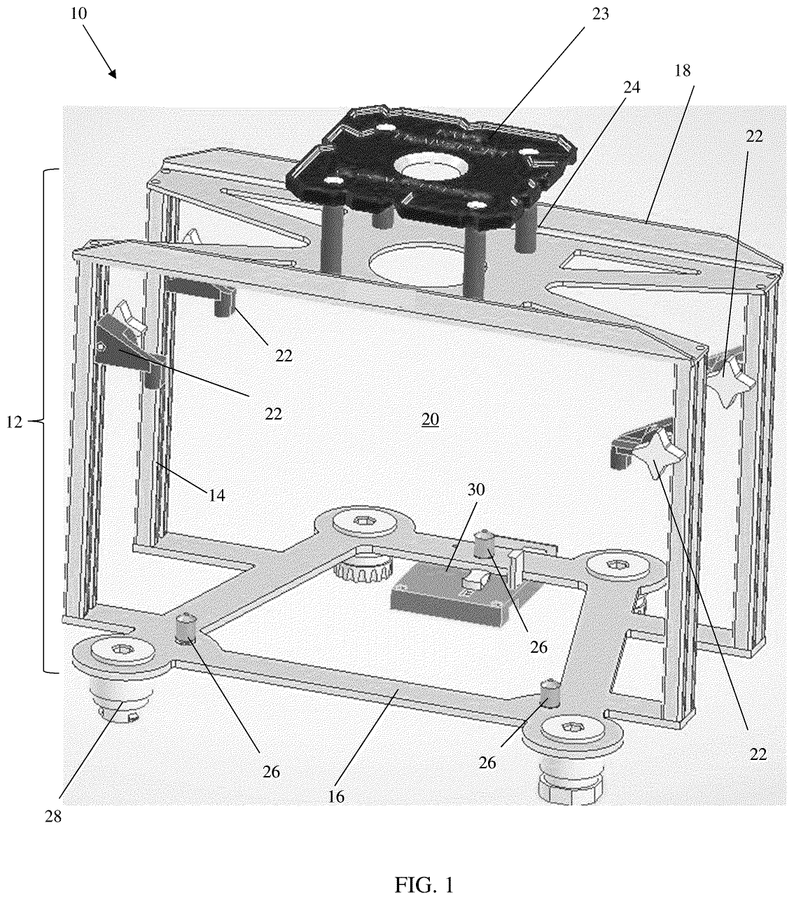

FIG. 1 shows a fixture in accordance with aspects of the present disclosure. In embodiments, the fixture 10 includes a frame 12 comprising vertical rails 14, a bottom frame section (e.g., a base) 16 and an upper frame section 18. The vertical rails 14, bottom frame section 16 and upper frame section 18 form an open space 20 that is sized to accommodate and hold a horizontal wafer shipper, regardless of its height. In embodiments, the horizontal wafer shipper will rest on the bottom frame section 14 and will be secured to the frame 12 by clamps 22 located on each of the vertical rails 14. The fixture 12 may be made from any appropriate materials including, for example, plastic, metal, or any combinations thereof.

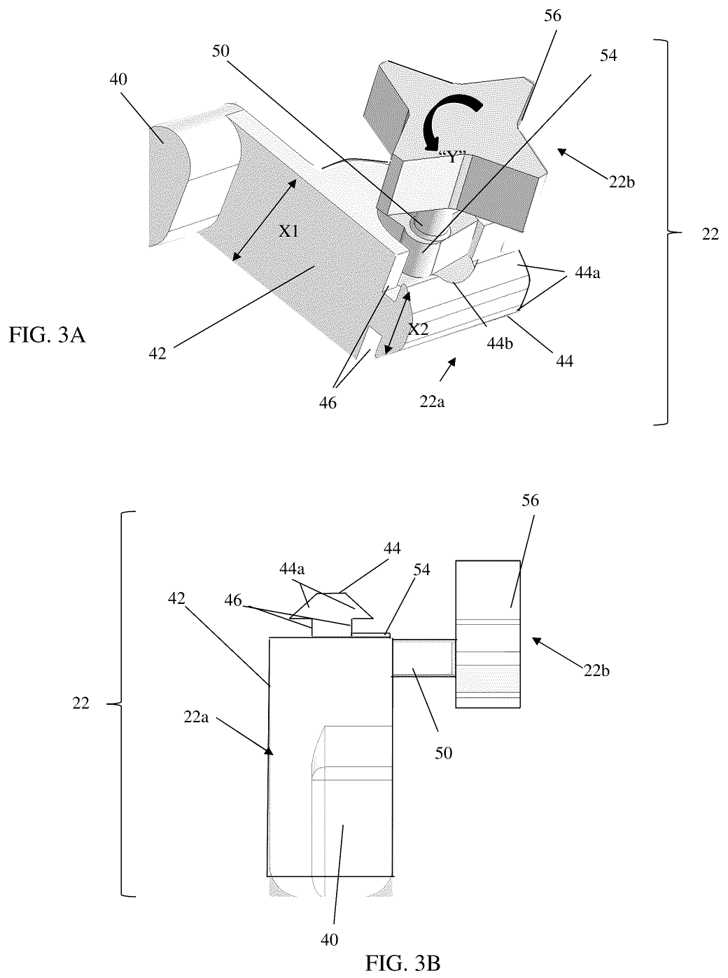

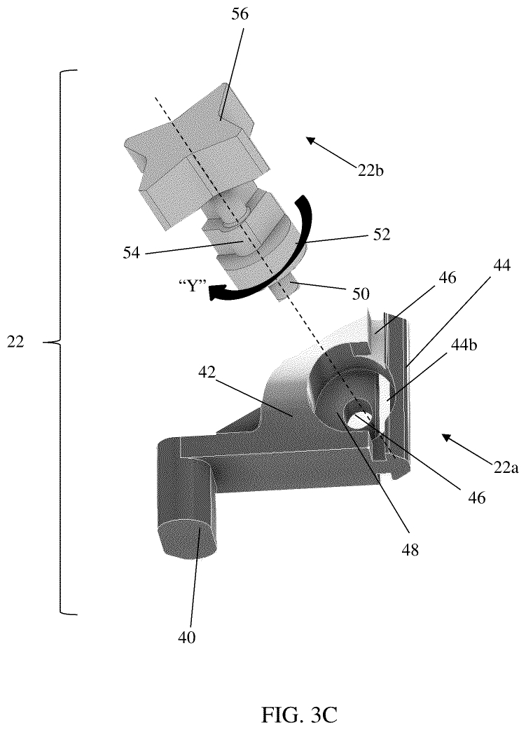

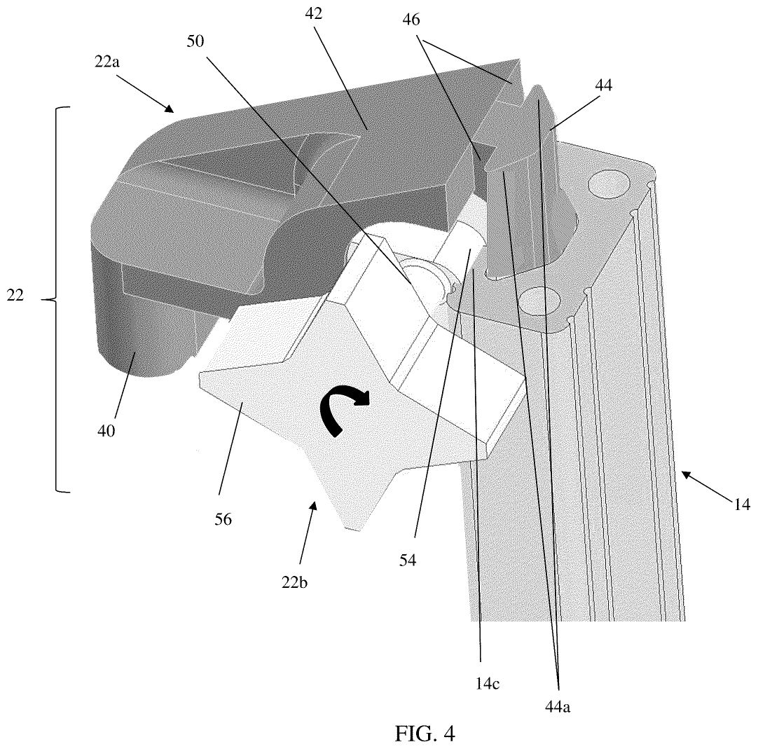

The clamps 22 can be a locking mechanism or other restraint which securely hold the horizontal wafer shipper inside the fixture 12 during transport and storage. In more specific embodiments and as described in more detail with respect to FIGS. 3A-4, the clamps 22 may be cam mechanisms capable of sliding vertically along the vertical rails 14 (as depicted by the double arrow labeled “x”) and securing the horizontal wafer shipper of any height to the frame 12 through a friction or interfering fitting. The clamps 22 may be manually, electrically, or pneumatically activated and controlled.

Still referring to FIG. 1, a mounting plate 23 is mounted to a top of the frame 12 and more specifically to the upper frame section 18. In embodiments, the mounting plate 23 may be spaced apart from the upper frame section 18 by spacers 24. For example, the spacers 24 may be bolts that connect the mounting plate 23 to the frame 12. The mounting plate 23 may be designed to enable pick up and transport from any known Automated Material Handling System (AMHS) or overhead transport (OHT).

The bottom frame section 16 may include an internal locating structure 26 extending upwardly into the space 20. In embodiments, the internal locating structure 26 may be locating pins for aligning the horizontal wafer shipper within the frame 12. In more specific embodiments, the internal locating structure 26 may be kinematic pins or other locating fixtures/guides to ensure correct placement and positioning of the horizontal wafer shipper, in addition to maintaining the fixture's center of gravity during automated material handling system transport.

The bottom frame section 16 also includes mounting mechanisms 28, which are used to interface with and couple to, for example, a base of a carrier. In embodiments, the carrier may be a front opening universal pod (FOUP). In further embodiments, the mounting mechanisms 28 may interface with a standard semi spec FOUP load port though the use of kinematic pins. This may be a main interface between the fixture 10 and a load port. The fixture 10 may also interface on a flat surface or with other orientation hardware that may or may not be unique to the horizontal wafer shipper (HWS) automation. In embodiments, the mounting mechanisms 28 may be any conventional mechanism adapted and structured to hold the FOUP. The mounting mechanisms 28 can be secured to the frame by any conventional mechanism such as a bolt.

The fixture 12 may also include a computer, battery, and/or control system and software to enable automatic interfacing with the horizontal wafer shipping packing equipment, bagging equipment, or other handling/processing equipment equipped with, for example, FOUP load ports. Also, the fixture 12 may include an RFID holder, barcode, or other tracking and or human readable identifier. The computer, battery, and/or control system and software and RFID holder, etc. are generally depicted at reference number 30.

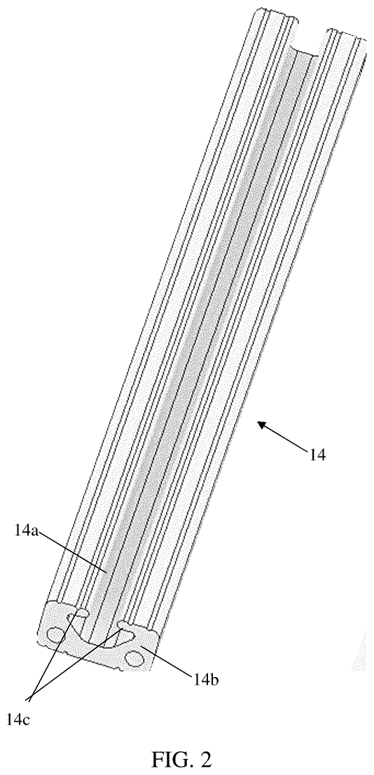

FIG. 2 shows an exploded view of the rail 14 used with the fixture in accordance with aspects of the present disclosure. In embodiments, the rail 14 includes a groove 14a running along its entire length. The groove 14a is configured to accommodate the clamps 22 as shown in more detail with respect to FIG. 4. The groove 14a is defined by opposing sidewalls 14b and inwardly extending flanges 14c extending from each of the opposing sidewalls 14b. In embodiments, the inwardly extending flanges 14c can engage with the clamp 22 for securing the clamp 22 to the rail 14 at different heights as described in FIG. 4.

FIGS. 3A-3C show various views of the clamp 22 used with the fixture 12 in accordance with aspects of the present disclosure. More specifically, FIG. 3A shows a perspective view of the clamp 22, FIG. 3B shows a side view of the clamp 22, and FIG. 3C shows an exploded view of the clamp 22. Referring to FIGS. 3A-3C, the clamp 22 may be a cam mechanism comprising a first part 22a and a second part 22b. The first part 22a fits into and is capable of vertically sliding within the groove 14a of the rail 14; whereas the second part 22b includes a cam mechanism 54 that provides a friction or interference fit to lock and unlock the clamp 22 on the rail 14.

More specifically, the first part 22a includes an engagement mechanism 40 attached to a main body 42. The engagement mechanism 40 may be a hook or other protrusion that extends downwardly from the main body 42. In embodiments, the engagement mechanism 40 may be used to engage with and contact a top surface of the horizontal wafer shipper. For example, in the locked position of the clamp 22, the engagement mechanism 40 will contact and securely holding the horizontal wafer shipper in place.

A flange 44 extends from the main body 42. The flange 44 includes projections 44a extending perpendicular to the horizontal plane of the main body 42. In this way, channels 46 are formed between the projections 44a and an edge of the main body 42. The flange 44 is shaped and sized to fit within the groove 14a of the rail 14, with the channels 46 sliding along the inwardly extending flanges (e.g., lips) 14c of the rail 14. In embodiments, the projections 44a of the flange 44 may have a height “X2” which is less than the height “X1”of the main body 42.

As shown in FIG. 3C, for example, the main body 42 of the first part 22a also includes an opening 46 and a hollow or recessed portion 48. The hollow or recessed portion 48 should preferably be circular and extends beyond the channel 46 and into the upper flange 44a. This will result in an arc shaped recess in the flange 44a as shown at reference numeral 44b. In embodiments, the opening 46 will accommodate a shaft 50 of the second part 22b of the clamp 22 and the hollow or recessed portion 48 will accommodate a circular bearing 52 of the second part 22b of the clamp 22. Accordingly, the second part 22b can be inserted into the first part 22a and rotated about a longitudinal axis of the second part 22b.

As shown further in FIGS. 3A-3C, the second part 22b includes a cam mechanism 54, which is attached to the shaft 50 and rotatable about the about the “Y” axis using a knob or handle 56. As should be understood by those of skill in the art, the cam mechanism 54 is a rotatable eccentric disc or other shape which will interact or contact with one of the inwardly extending flanges 14c to lock and unlock the clamp 22 to the rail 14. For example, as shown in the locked position of FIGS. 3A, 3B and 4, the cam mechanism 54, e.g., rotatable eccentric disc, will extend beyond a surface of the main body 42 of the first part 22a.

FIG. 4 shows the clamp 22 in a locked position along a length of the rail 14. In this locked position, the cam mechanism 54 of the clamp 22 will engage with the rail 14 of the fixture by rotating the knob 56 clockwise. For example, rotating the knob 56 will allow the cam mechanism 54 to engage with the rail 14 and, more particularly, with the inwardly extending flanges 14c of the rail 14.

More specifically, in the locked and unlocked position, the inwardly extending flanges 14c of the rail 16 will be guided within the channel 46 formed between the projections 44a of the flange 44 (e.g., extending perpendicular to the horizontal plane of the main body 42) and the main body 42. The cam mechanism 54 will be located on an outer side of the inwardly extending flanges 14c and the projections 44a of the flange 44 will be located on an inner side of the inwardly extending flanges 14c. In this way, in the locked position and upon activation of the cam mechanism 54, the inwardly extending flanges 14c will be tightly squeezed between the cam mechanism 54 and the projections 44a of the flange 44, effectively locking the clamp 22 in position along a height of the rail 14. That is, in the locked position, the cam mechanism 54 will place a force or pressure on the inwardly extending flanges 14c to lock the clamp 22 in place along the height of the rail 14. In the unlocked position, on the other hand, the cam mechanism 54 will be moved out of engagement with the inwardly extending flange 14c, effectively allowing the clamp 22 to slide along the rail 14 to different heights.

The fixture and method(s) as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A fixture comprising:
a frame comprising a mounting space provided between a top section, a bottom section and rails extending between the top section and the bottom section; and
a clamp slidably mounted to the rails, the clamp including a locking mechanism that locks the clamp to the frame at different heights of the rails.

2. The fixture of claim 1, wherein the locking mechanism comprises a rotatable cam mechanism that engages the rails.

3. The fixture of claim 1, wherein the rails comprise a groove provided between sidewalls and flanges inwardly extending from the sidewalls.

4. The fixture of claim 3, wherein the clamp comprises a first part comprising a flange corresponding in shape and which is slidable within the groove of the rails.

5. The fixture of claim 4, wherein the first part of the clamp further comprises a channel which accommodates the inwardly extending flanges of the rails.

6. The fixture of claim 4, wherein the first part includes an engagement mechanism which extends downwardly from an end of the main body.

7. The fixture of claim 5, wherein the clamp comprises a second part rotatably mounted within a recessed portion of the first part.

8. The fixture of claim 7, wherein the second part of the clamp includes the locking mechanism that is engageable with one of the inwardly extending flanges of the rails.

9. The fixture of claim 5, wherein the locking mechanism comprises a cam mechanism that extends beyond a surface of a main body and which engages and disengages with one of the inwardly extending flanges of the rails as it is rotated within the first part.

10. The fixture of claim 1, wherein the frame includes a mounting plate mounted to the upper section of the frame.

11. The fixture of claim 1, further comprising locating guides extending into the mounting space of the frame.

12. The fixture of claim 1, further comprising a holder structured to store identification information.

13. A fixture comprising:
a frame comprising rails each with a groove along a longitudinal axis and which are defined by opposing inwardly extending flanges; and
a locking mechanism slidably mounted to the rails and which rotatably engages with one of the opposing inwardly extending flanges.

14. The fixture of claim 13, wherein the locking mechanism comprises opposing channels and a flange between the channels, the opposing channels accommodate the opposing inwardly extending flanges of the rails and the flange fits within the groove of the rails.

15. The fixture of claim 14, wherein the locking mechanism includes a cam that extends to within the channel and is engageable with the one of the opposing inwardly extending flanges of the rails.

16. The fixture of claim 15, wherein the cam is rotatable into and out of contact with the one of the opposing inwardly extending flanges of the rails.

17. The fixture of claim 13, wherein the locking mechanism comprises an engagement mechanism which extends downwardly from an end of a main body.

18. The fixture of claim 13, further comprising locating guides extending into a mounting space of the frame.

19. A fixture comprising:
a frame comprising rails extending between a top section and a bottom section, the rails comprising a groove along a longitudinal axis; and
a locking mechanism slidably mounted within the groove of the rails, the locking mechanism comprising a rotating cam mechanism and opposing channels between a main body and protrusions extending from a flange, the channels riding along the rails and the rotating cam mechanism being rotatable into and out of contact the rails.

20. The fixture of claim 19, wherein the rotating cam mechanism extends beyond a surface of the main body into one of the opposing channels and contacts with an inwardly extending flange forming part of the groove of the rails.
